(19) United States
(12) Patent Application Publication
(10) Pub. No.: US 2024/0071768 A1
(43) Pub. Date: Feb. 29, 2024

(54) SEMICONDUCTOR DEVICE FABRICATION APPARATUS AND SEMICONDUCTOR DEVICE FABRICATION METHOD USING THE SAME

(71) Applicant: Samsung Electronics Co., Ltd., Suwon-si (KR)

(72) Inventors: Sang - Il CHOI, Suwon-si (KR); Yeong Jun JO, Suwon-si (KR); Seong Gi JEON, Suwon-si (KR)

(73) Assignee: Samsung Electronics Co., Ltd., Suwon-si (KR)

(21) Appl. No.: 18/359,000

(22) Filed: Jul. 26, 2023

(30) Foreign Application Priority Data
Aug. 25, 2022 (KR) 10-2022-0106602

(51) Int. Cl. H01L 21/304; B23K 26/0622; H01L 21/683

(52) U.S. Cl. CPC H01L 21/304; B23K 26/0624; H01L 21/6836; B23K 2101/40; H01L 2221/68327

(57) ABSTRACT

A semiconductor device fabrication apparatus including a grinder comprising a grinding part, the grinding part configured to grind a first surface of a substrate, a laser emitter configured to emit a femtosecond pulse laser to the first surface of the substrate transferred from the grinder, and a mount configured to attach a die attach film to the first surface of the substrate transferred from the laser emitter, wherein the grinding part is configured to grind the first surface of the substrate, which has been introduced into the grinder, and the laser emitter is configured to emit the femtosecond pulse laser to the ground first surface of the substrate may be provided.

### CROSS-REFERENCE TO RELATED APPLICATION

This application claims priority from Korean Patent Application No. 10-2022-0106602 filed on Aug. 25, 2022 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to semiconductor device fabrication apparatuses and/or a semiconductor device fabrication methods using the same.

### 2. Description of the Related Art

There has been a strong demand for semiconductor devices to have high density and high integration in response to the higher functionality in electronic devices and the expansion to mobile applications. As a result, large capacity and high density Integrated Circuit (IC) package is being developed.

In the methods of fabricating the semiconductor device, after grinding and/or polishing a wafer, a supporting film (e.g., die attach film (DAF)) is bonded to the wafer, and a process of cutting the wafer into individual semiconductor elements may be performed.

In the process of polishing the wafer, it is difficult to completely remove the cracks on the surface and inside of the wafer, which degrades reliability of the semiconductor elements.

### SUMMARY

Aspects of the present disclosure provide semiconductor device fabrication methods capable of fabricating a semiconductor device with improved reliability.

Aspects of the present disclosure also provide semiconductor device fabrication apparatuses capable of fabricating semiconductor devices with improved reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor device fabrication apparatus may include a grinder comprising a grinding part, the grinding part configured to grind a first surface of a substrate, a laser emitter configured to emit a femtosecond pulse laser to the first surface of the substrate transferred from the grinder, and a mount configured to attach a die attach film to the first surface of the substrate transferred from the laser emitter. The grinding part may be configured to grind the first surface of the substrate, which has been introduced into the grinder, and the laser emitter may be configured to emit the femtosecond pulse laser to the ground first surface of the substrate.

According to another aspect of the present disclosure, a semiconductor device fabrication apparatus may include a transferer configured to transfer a substrate, the substrate having a first surface on which a circuit pattern is provided and a second surface opposed to the first surface, a grinder comprising a first grinding part and a second grinding part and a polishing part, each of the first grinding part and the second grinding part configured to grind the second surface of the substrate transferred by the transferer, and the polishing part configured to polish the ground second surface of the substrate, a laser emitter configured to emit a femtosecond pulse laser to the second surface of the substrate transferred from the grinder, a controller configured to control an operation of the polishing part, and a mount configured to attach a die attach film to the first surface of the substrate transferred from the laser emitter. The first grind part may be configured to perform a first grinding process on the second surface of the substrate introduced into the grinder, the second grind part may be configured to perform a second grinding process on the second surface of the substrate on which the first grinding process has been performed, and the laser emitter may be configured to emit the femtosecond pulse laser to the second surface of the substrate on which the first and second grinding processes have been performed.

According to still another aspect of the present disclosure, a semiconductor device fabrication method may include attaching a protective tape to a first surface of a substrate on which a circuit pattern is provided, introducing the substrate with the protective tape attached into a grinder, performing, through a first grinding part of the grinder, a first grinding process on a second surface of the substrate introduced into the grinder, performing, through a second grinding part of the grinder, a second grinding process on the second surface of the substrate on which the first grinding process has been performed, emitting a femtosecond pulse laser to the second surface of the substrate on which the second grinding process has been performed, and detaching the protective tape attached to the first surface of the substrate.

According to yet another aspect of the present disclosure, a semiconductor device fabrication apparatus may include a transferer configured to transfer a substrate having a first surface on which a circuit pattern is provided and a second surface opposed to the first surface, a grinder including first and second grinding parts configured to grind the second surface of the substrate transferred by the transferer and a polishing part configured to polish the ground second surface of the substrate, a laser emitter configured to emit a femtosecond pulse laser to the second surface of the substrate transferred from the grinder, a controller configured to control an operation of the polishing part, and a mount configured to attach a die attach film to the first surface of the substrate transferred from the laser module, wherein the femtosecond pulse laser is emitted to the second surface of the substrate on which first and second grinding processes have been performed.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail some example embodiments thereof with reference to the attached drawings, in which:

FIG. 1 is a schematic plan view of a semiconductor device fabrication apparatus according to an example embodiment;

FIG. 2 is a schematic view of a grinding part according to an example embodiment;

FIG. 3 is a schematic view of a laser module according to an example embodiment;

FIG. 4 is a diagram schematically illustrating a shape of a substrate surface ground by a grinder module according to an example embodiment;

FIG. 5 is a diagram schematically illustrating a shape of a substrate surface polished by a conventional polishing part;

FIG. 6 is a diagram schematically illustrating a shape of a substrate surface irradiated with a laser by a laser module after the substrate surface is ground by a grinder module according to an example embodiment; and

FIG. 7 is a flowchart of a semiconductor device fabrication method using a semiconductor device fabrication apparatus according to an example embodiment.

### DETAILED DESCRIPTION

Hereinafter, some example embodiments of the present disclosure will be described with reference to the attached drawings.

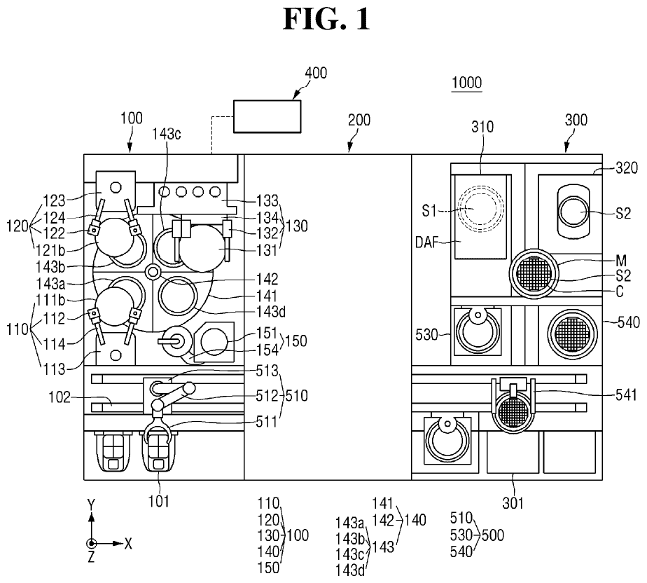

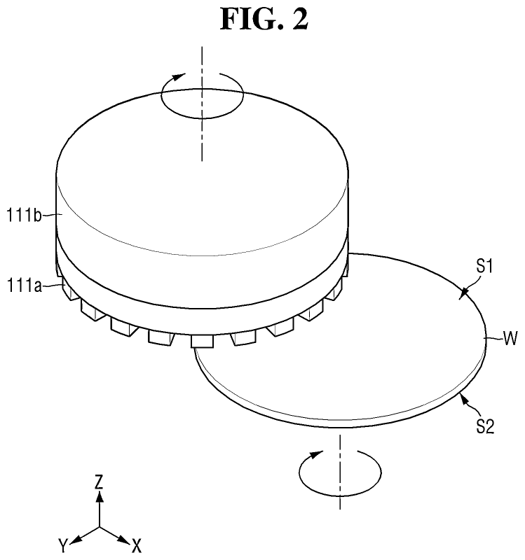

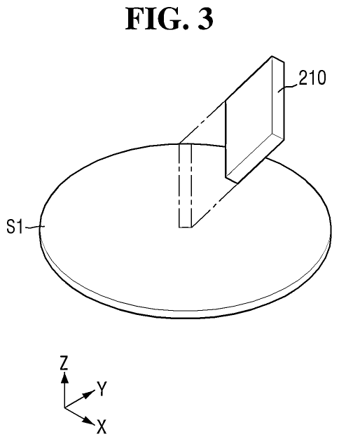

FIG. 1 is a schematic plan view of a semiconductor device fabrication apparatus according to an example embodiment. FIG. 2 is a schematic view of a grinding part according to an example embodiment. FIG. 3 is a schematic view of a laser module according to an example embodiment.

A semiconductor device fabrication apparatus 1000 may include a grinder module (or alternatively, a grinder) 100, a laser module (or alternatively, a laser emitter) 200, a mount module (or alternatively, a mount) 300, a control module (or alternatively, a controller) 400, and a transfer module (or alternatively, a transferer) 500.

The grinder module 100 may include a first grinding part 110, a second grinding part 120, and a polishing part 130.

A substrate W may include a first surface S1 and a second surface S2 that is opposed to the first surface S1. In some example embodiments, the first surface S1 of the substrate W may refer to a back surface, and the second surface S2 of the substrate W may refer to a patterned surface on which a circuit pattern is formed (e.g., a front surface).

The substrate W with a protective tape attached to the second surface S2 thereof may be transferred to the grinder module 100 by a first transfer part 510, which will be described below. The protective tape is provided to protect the circuit pattern on the second surface S2. The first grinding part 110 may grind the first surface S1 of the substrate W introduced into the grinder module 100 from the transfer module 500.

The first grinding part 110 may include a first rotating part 111b, a first vertical moving part 112, a first driving part 113, and a first connecting part 114.

Referring to FIG. 2, the first rotating part 111b may include a first grinding wheel 111a that performs a first grinding process on the first surface S1 of the substrate W. For example, the first grinding wheel 111a may be a diamond wheel. The first rotating part 111b may grind the substrate W while rotating in a clockwise or counterclockwise direction about a rotation shaft.

The first vertical moving part 112 may move the first rotating part 1l1b in a vertical direction Z. The first driving part 113 may drive the first vertical moving part 112. The first connecting part 114 may connect the first driving part 113 to the first vertical moving part 112.

The second grinding part 120 may grind the first surface S1 of the substrate on which the first grinding process has been performed.

The second grinding part 120 may include a second rotating part 121b, a second vertical moving part 122, a second driving part 123, and a second connecting part 124.

The second rotating part 121b may include a second grinding wheel that performs a second grinding process on the first surface S1 of the substrate W. The second rotating part 121b may grind the substrate W while rotating in a clockwise or counterclockwise direction about the rotation shaft. The second grinding wheel may grind the substrate W more precisely than the first grinding wheel. For example, the description on the shape of the first grinding wheel shown in FIG. 2 may similarly apply to the second grinding wheel.

The second vertical moving part 122 may move the second rotating part 121b in the vertical direction Z. The second driving part 123 may drive the second vertical moving part 122. The second connecting part 124 may connect the second driving part 123 to the second vertical moving part 122.

The polishing part 130 may polish the first surface S1 of the substrate W on which the second grinding process has been performed.

The polishing part 130 may include a third rotating part 131, a third vertical moving part 132, a third driving part 133, and a third connecting part 134.

Although not specifically illustrated, the third rotating part 131 may include a polishing pad to polish the first surface S1 of the substrate W. The polishing pad may polish the substrate W more precisely than the first grinding wheel 111a or the second grinding wheel.

The third vertical moving part 132 may move the third rotating part 131 in the vertical direction Z. The third driving part 133 may drive the third vertical moving part 132. The third connecting part 134 may connect the third driving part 133 to the third vertical moving part 132.

The substrate support unit 140 may include a rotating plate 141, a rotation shaft 142, and a support part 143.

The rotating plate 141 may rotate in a clockwise or counterclockwise direction about the rotation shaft 142. In a plan view, the rotating plate 141 may include a first region, a second region, and a third region that correspond to the first grinding part 110, the second grinding part 120, and the polishing part 130, respectively.

The support part 143 may be disposed below the first grinding part 110, the second grinding part 120, and the polishing part 130 to support the substrate W. The support part 143 may include a first support part 143a, a second support part 143b, and a third support part 143c that correspond to the first region, the second region, and the third region, respectively.

The substrate W on which the first grinding process, the second grinding process, and/or the polishing process has been performed may be held by the support part 143. For example, the support part 143 may be a vacuum suction part, but is not limited thereto.

The cleaning unit 150 may include a cleaning part 151 that cleans the substrate W on which the first grinding process, the second grinding process, and/or the polishing process has been performed. The ground or polished substrate W may be transferred to the cleaning unit 150 through a fourth support part 143d and the cleaning unit 150 may include a transfer part 154 that transfers the transferred substrate W to a cleaning part 151.

The laser module 200 may emit a femtosecond (10⁻¹⁵ seconds) pulse laser to the first surface S1 of the substrate W transferred from the grinder module 100. The laser module 200 may emit a femtosecond pulse laser to the first surface S1 of the substrate W on which the first and second grinding processes have been performed.

The laser module 200 may include a laser irradiating part 210, a driving part, and a suction part.

Referring to FIG. 3, the laser irradiating part 210 may irradiate a laser in the shape of a line beam to the first surface S1 of the substrate W. Although not specifically illustrated, the driving part may move the laser irradiating part 210 on the substrate W in a direction parallel to the first surface S1 of the substrate W. The laser irradiating part 210 may move a plurality of times in a direction parallel to the surface S1 of the substrate W to irradiate a laser a plurality of times to the substrate W, but example embodiments are not limited to this case. The thickness of the substrate W removed by the laser irradiation may be 5 um or less, but is not limited thereto.

Although not specifically illustrated, the suction part may support the substrate W, under the substrate W. The suction part may be configured in a front surface suction manner in order to support the substrate W which has a thickness reduced through the grinder module 100.

Accordingly, the substrate W may be smoothly handled in the process of emitting a femtosecond pulse laser to the substrate W with a reduced thickness.

The mount module 300 may include a die attach film (DAF) attaching part 310 and a protective tape detaching part 320.

The DAF attaching part 310 may attach a DAF to the first surface S1 of the substrate W transferred from the laser module 200.

The protective tape detaching part 320 may detach a protective tape attached to the second surface S2 of the substrate W. By emitting above-described femtosecond pulse laser to the first surface S1 of the substrate W, heat damage to the protective tape may be mitigated or prevented and transfer of excessive heat to the second surface S2 of the substrate W may be mitigated or prevented.

Thereafter, the substrate W having a plurality of semiconductor chips C formed on the first surface S1 may be transferred by a fourth transfer part 540 which will be described below. The plurality of semiconductor chips C may be transferred while being attached to the substrate W using a metal layer M. The metal layer M may include, for example, stainless steel (SUS), but is not limited thereto.

Then, the substrate W may be transferred from the mount module 300 and the plurality of semiconductor chips C formed on the first surface S1 of the substrate W may be divided into individual chips.

The control module 400 may control whether to operate the polishing part 130.

For example, when the control module 400 determines to not operate the polishing part 130, a polishing process may not be performed, and a femtosecond pulse laser may be emitted to the first surface S1 of the substrate W on which the second grinding process has been performed. In this case, the polishing part 130 and the substrate W may not be in direct contact with each other, and at least a portion of the first surface S1 of the substrate W may be removed.

In another example, when the control module 400 determines to operate the polishing part 130, a polishing process may be performed on the first surface S1 of the substrate W on which the second grinding process has been performed, and a femtosecond pulse laser may be emitted to the first surface S1 of the substrate W on which the second grinding process has been performed.

The control mode (or alternatively, controller) may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The transfer module 500 may include first to fourth transfer parts 510, 520, 530, and 540.

The first transfer part 510 may introduce the substrate W into the grinder module 100 from a cassette 101 which accommodates the substrate W. The first transfer part 510 may include a substrate hand 511, a transfer arm 512, and a driving part 513 to transfer the substrate W from the cassette 101.

Although the transfer module 500 is illustrated as transferring the substrate W along a guide rail 102, but example embodiments are not limited to this case. That is, the transfer module 500 may transfer the substrate W by means of transfer other than the guide rail 102.

Although not specifically illustrated, the second transfer part may introduce the substrate W into the laser module 200 from the grinder module 100. For example, the thickness of the substrate W introduced into the laser module 200 from the grinder module may be 70 um or less. In this case, the target to be irradiated with a laser may be a substrate having a thickness of 70 um or less after the grinding process and/or the polishing process.

The third transfer part 530 may introduce the substrate W into the mount module 300 from the laser module 200.

The fourth transfer part 540 may transfer the substrate W into a substrate loading part 301 using a second transfer arm 541 in order to form the plurality of semiconductor chips C into individual semiconductor chips.

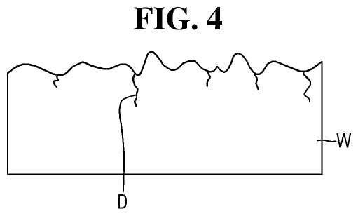

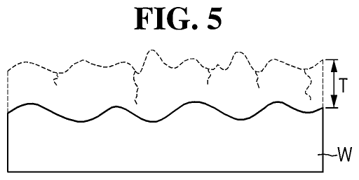

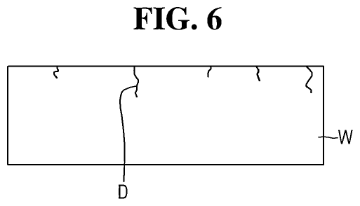

FIG. 4 is a diagram schematically illustrating a shape of a substrate surface ground by a grinder module according to an example embodiment. FIG. 5 is a diagram schematically illustrating a shape of a substrate surface polished by a conventional polishing part. FIG. 6 is a diagram schematically illustrating a shape of a substrate surface irradiated with a laser by a laser module after the substrate surface is ground by a grinder module according to an example embodiment.

Referring to FIG. 4, due to the temperature and pressure accompanying the grinding process, defects D such as cracks on the surface and inside of the substrate W may occur.

Although not specifically shown, due to a contact polishing process, the defects D such as cracks on the surface and inside of the substrate W may be further grown.

Referring to FIG. 5 and FIG. 6, at least a portion of the substrate W may be removed in a non-contact manner by a laser module 200 according to an example embodiment. For example, the thickness of the substrate W to be removed may be 5 um or less. Accordingly, the defects D on the surface and inside of the substrate W may be reduced compared to the conventional art, and thus a semiconductor device with improved reliability may be fabricated.

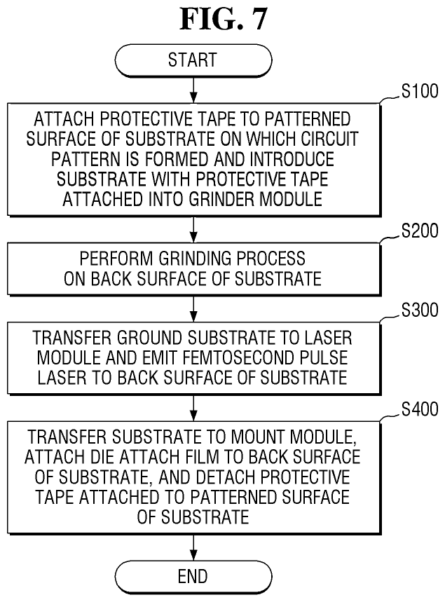

FIG. 7 is a flowchart of a semiconductor device fabrication method using a semiconductor device fabrication apparatus according to an example embodiment. For convenience of description, the same content as those described with reference to FIGS. 1 to 6 will not be described.

First, a protective tape may be attached to a patterned surface S2 of a substrate W on which a circuit pattern is formed. Then, the substrate W with the protective tape attached may be introduced into a grinder module 100 through a transfer module (S100).

A back surface S1 of the substrate W introduced into the grinder module 100 may be subject to a first grinding process through a first grinding part 110, and the back surface S1 of the substrate W on which the first grinding process has been performed may be subject to a second grinding process through a second grinding part 120 (S200).

Thereafter, a femtosecond pulse laser may be emitted to the back surface S1 of the substrate W on which the second grinding process has been performed (S300).

For example, when a control module 400 determines to not operate a polishing part 130, a polishing process may not be performed, and a femtosecond pulse laser may be emitted to the back surface S1 of the substrate W on which the second grinding process has been performed. In this case, the polishing part 130 and the substrate W may not be in direct contact with each other, and at least a portion of the back surface S1 of the substrate W may be removed.

In another example, when the control module 400 determines to operate the polishing part 130, a polishing process may be performed on the back surface S1 of the substrate W on which the second grinding process has been performed, and a femtosecond pulse laser may be emitted to the back surface S1 of the substrate W on which the second grinding process has been performed.

Then, a DAF may be attached to the back surface S1 of the substrate W transferred from the laser module 200 and the protective tape attached to the patterned surface S2 of the substrate W may be detached (S400).

Thereafter, the substrate W may be transferred to a substrate loading part 301 in order to form a plurality of semiconductor chips C into individual semiconductor chips.

While the present disclosure has been particularly shown and described with reference to certain example embodiments thereof, it will be understood by those of ordinary skill in the art that various changes in form and details may be made therein without departing from the spirit and scope of the present disclosure as defined by the appended claims and their equivalents.

What is claimed:

1. A semiconductor device fabrication apparatus comprising:
a grinder comprising a grinding part, the grinding part configured to grind a first surface of a substrate;
a laser emitter configured to emit a femtosecond pulse laser to the first surface of the substrate transferred from the grinder; and
a mount configured to attach a die attach film to the first surface of the substrate transferred from the laser emitter,
wherein the grinding part is configured to grind the first surface of the substrate, which has been introduced into the grinder, and the laser emitter is configured to emit the femtosecond pulse laser to the ground first surface of the substrate.

2. The semiconductor device fabrication apparatus of claim 1, wherein
the grinding part comprises a first grinding part, a second grinding part, a polishing part, the first grinding part configured to perform a first grinding process on the first surface of the substrate, the second grinding part configured to perform a second grinding process on the first surface of the substrate on which the first grinding process has been performed, and the polishing part configured to polish the first surface of the substrate on which the second grinding process has been performed, and
the semiconductor device fabrication apparatus further comprises a controller configured to control an operation of the polishing part.

3. The semiconductor device fabrication apparatus of claim 2, wherein when the controller controls the polishing part to not operate, the laser emitter is configured to emit the femtosecond pulse laser to the first surface of the substrate on which the second grinding process has been performed.

4. The semiconductor device fabrication apparatus of claim 3, wherein the laser emitter is configured to remove at least a portion of the substrate by emitting the femtosecond pulse laser to the first surface of the substrate in a state in which the polishing part and the substrate are not in contact with each other.

5. The semiconductor device fabrication apparatus of claim 2, wherein when the controller controls the polishing part to operate,
the polishing part is configured to polish the first surface of the substrate on which the second grinding process, and
the laser emitter is configured to emit the femtosecond pulse laser to the polished first surface of the substrate.

6. The semiconductor device fabrication apparatus of claim 1, wherein a thickness of the substrate introduced into the laser emitter from the grinder is 70 um or less.

7. The semiconductor device fabrication apparatus of claim 1, wherein the laser emitter further comprises a suction part configured to support the substrate in a process of emitting the femtosecond pulse laser.

8. The semiconductor device fabrication apparatus of claim 1, wherein the laser emitter comprises a laser irradiating part, which is configured to irradiate the femtosecond pulse laser to the first surface of the substrate and move on the substrate in a direction parallel to the first surface of the substrate.

9. The semiconductor device fabrication apparatus of claim 8, wherein the laser irradiation part is configured to remove 5 um or less of a thickness of the substrate.

10. The semiconductor device fabrication apparatus of claim 1, wherein when the substrate having a protective tape attached to a second surface opposed to the first surface is introduced into the grinder, the laser emitter is configured to emit the femtosecond pulse laser to the first surface of the substrate.

11. A semiconductor device fabrication apparatus, comprising:
a transferer configured to transfer a substrate, the substrate having a first surface on which a circuit pattern is provided and a second surface opposed to the first surface;
a grinder comprising a first grinding part and a second grinding part and a polishing part, each of the first grinding part and the second grinding part configured to grind the second surface of the substrate transferred by the transferer, and the polishing part configured to polish the ground second surface of the substrate;
a laser emitter configured to emit a femtosecond pulse laser to the second surface of the substrate transferred from the grinder;
a controller configured to control an operation of the polishing part; and
a mount configured to attach a die attach film to the first surface of the substrate transferred from the laser emitter,
wherein the first grind part is configured to perform a first grinding process on the second surface of the substrate introduced into the grinder,
the second grind part is configured to perform a second grinding process on the second surface of the substrate on which the first grinding process has been performed, and
the laser emitter is configured to emit the femtosecond pulse laser to the second surface of the substrate on which the first and second grinding processes have been performed.

12. The semiconductor device fabrication apparatus of claim 11, wherein when the controller controls the polishing part to not operate, the laser emitter is configured to the femtosecond pulse laser to the second surface of the substrate on which the second grinding process has been performed.

13. The semiconductor device fabrication apparatus of claim 12, wherein the laser emitter is configured to remove at least a portion of the substrate by emitting the femtosecond pulse laser to the second surface of the substrate in a state in which the polishing part and the substrate are not in direct contact with each other.

14. The semiconductor device fabrication apparatus of claim 11, wherein when the controller controls the polishing part to operate,
the polishing part is configured to polish the second surface of the substrate on which the second grinding process, and
the laser emitter is configured to emit the femtosecond pulse laser to the polished second surface of the substrate.

15. The semiconductor device fabrication apparatus of claim 11, wherein the laser emitter comprises a laser irradiating part, which is configured to irradiate a laser in a shape of a line beam to the second surface of the substrate and move a plurality of times in a direction parallel to the second surface of the substrate to remove at least a portion of the substrate.

16. A semiconductor device fabrication method comprising:
attaching a protective tape to a first surface of a substrate on which a circuit pattern is provided;
introducing the substrate with the protective tape attached into a grinder;
performing, through a first grinding part of the grinder, a first grinding process on a second surface of the substrate introduced into the grinder;
performing, through a second grinding part of the grinder, a second grinding process on the second surface of the substrate on which the first grinding process has been performed;
emitting a femtosecond pulse laser to the second surface of the substrate on which the second grinding process has been performed; and
detaching the protective tape attached to the first surface of the substrate.

17. The semiconductor device fabrication method of claim 16, further comprising:
controlling, through a controller, a polishing part of the grinder to not operate; and
polishing, through the polishing part, the second surface of the substrate on which the second grinding process has been performed.

18. The semiconductor device fabrication method of claim 17, wherein the emitting comprises emitting the femtosecond pulse laser to the polished second surface of the substrate.

19. The semiconductor device fabrication method of claim 16, further comprising:
in response to a controller controlling a polishing part of the grinder to not operate, the polishing part configured to a polishing process to the second surface of the substrate on which the second grinding process has been performed, and
the emitting comprises emitting the femtosecond pulse laser to the second surface of the substrate on which the second grinding process has been performed and the polishing process has not been performed.

20. The semiconductor device fabrication method of claim 19, wherein the emitting removes at least a portion of the substrate in a state in which the polishing part and the substrate are not in contact with each other.
